(19) United States
(12) Patent Application Publication
(10) Pub. No.: US 2026/0290420 A1
(43) Pub. Date: Sep. 24, 2026

(54) MEMORY DEVICE, OPERATING METHOD THEREOF, AND MEMORY SYSTEM

(71) Applicant: Yangtze Memory Technologies Co., Ltd., Wuhan (CN)

(72) Inventors: Wei QI, Wuhan (CN); Xiangnan ZHAO, Wuhan (CN); Hongtao LIU, Wuhan (CN); Lei JIN, Wuhan (CN); Da LI, Wuhan (CN)

(21) Appl. No.: 19/311,581

(22) Filed: Aug. 27, 2025

(30) Foreign Application Priority Data
Mar. 18, 2025 (CN) 202510323295.4

(51) Int. Cl. G11C 11/22; G11C 5/06; G11C 16/04; G11C 16/16; G11C 16/26; G11C 16/34; H10B 41/27; H10B 41/35; H10B 41/41; H10B 43/27; H10B 43/35; H10B 43/40; H10B 51/20; H10B 51/30; H10B 51/40

(52) U.S. Cl. CPC G11C 11/2277; G11C 5/063; G11C 11/223; G11C 11/2273; G11C 11/2275; G11C 16/0483; G11C 16/16; G11C 16/26; G11C 16/3445; H10B 41/27; H10B 41/35; H10B 41/41; H10B 43/27; H10B 43/35; H10B 43/40; H10B 51/20; H10B 51/30; H10B 51/40

(57) ABSTRACT

An example memory device includes: a memory cell array, a plurality of word lines, and a peripheral circuit configured to: apply a first verification voltage to a selected word line, where a plurality of memory cells connected to the selected word line includes a first group of memory cells and a second group of memory cells, threshold voltages for first memory cells in the first group of memory cells are smaller than the first verification voltage, and threshold voltages for second memory cells in the second group of memory cells are greater than or equal to the first verification voltage; and perform a program operation on at least a portion of the first memory cells in the first group of memory cells and the second memory cells in the second group of memory cells. Threshold voltages corresponding to the target memory states are smaller than the first verification voltage.

### CROSS-REFERENCE TO RELATED APPLICATIONS

This application claims priority to Chinese Patent Application No. 202510323295.4, filed on Mar. 18, 2025, which is hereby incorporated by reference in its entirety.

### FIELD OF TECHNOLOGY

The present disclosure relates to the field of semiconductor technologies, and in particular, to a memory device, an operating method thereof, and a memory system.

### BACKGROUND

Memory devices are storage devices for saving information in modern information technology. As a typical non-volatile semiconductor memory, NAND (Not-And)-type memories gradually become mainstream products in the memory market due to their high storage density, controllable production cost, and appropriate program/erase speeds. However, as requirements for storage devices continue to increase, there remains significant room for improvement in memory devices and their systems.

### SUMMARY

The example of the present disclosure provides a memory device and an operating method thereof, and a memory system.

In a first aspect, an example of the present disclosure provides a memory device, comprising: a memory cell array comprising a plurality of memory cells; a plurality of word lines coupled to the memory cell array; and a peripheral circuit coupled to the memory cell array and configured to: apply a first verification voltage to a selected word line to perform a first verification operation on a plurality of memory cells connected to the selected word line, wherein the plurality of memory cells connected to the selected word line comprise a first group of memory cells and a second group of memory cells, threshold voltages for first memory cells in the first group of memory cells are less than the first verification voltage, and threshold voltages for second memory cells in the second group of memory cells are greater than or equal to the first verification voltage; and perform a program operation on at least a portion of the first memory cells in the first group of memory cells and the second memory cells in the second group of memory cells, to program the at least a portion of the first memory cells and the second memory cells to respective target memory states, wherein threshold voltages corresponding to the target memory states are less than the first verification voltage.

In some examples, the peripheral circuit is further configured to: perform an erase operation on a memory block comprising the plurality of memory cells connected to the selected word line prior to the first verification operation, to cause the plurality of memory cells in the memory block to be in a first erased state, wherein the first verification voltage is greater than a minimum threshold voltage of a threshold voltage distribution for the first erased state and less than a maximum threshold voltage of the threshold voltage distribution for the first erased state.

In some examples, the peripheral circuit is configured to: apply a first pass voltage to an unselected word line during the first verification operation, wherein the first pass voltage is greater than the maximum threshold voltage of the threshold voltage distribution for the first erased state.

In some examples, the memory device further comprises: a plurality of bit lines coupled to the memory cell array, wherein the peripheral circuit is configured to: apply a first voltage to a selected bit line and apply a second voltage to an unselected bit line during the first verification operation, wherein the first voltage is greater than the second voltage.

In some examples, the peripheral circuit is configured to: apply a read voltage to the selected word line and apply a second pass voltage to the unselected word line during a read operation after the program operation, wherein the second pass voltage is greater than or equal to the first verification voltage and less than the first pass voltage.

In some examples, the second pass voltage is less than the maximum threshold voltage of the threshold voltage distribution for the first erased state.

In some examples, the peripheral circuit is configured to: during the program operation, apply a programming voltage to the selected word line connected to the at least a portion of the first memory cells and the second memory cells, and apply a third pass voltage to an unselected word line.

In some examples, the number of bits stored in each of the memory cells is N, the target memory state is one memory state among 2^{N} memory states comprising a second erased state and 2^{N}-1 non-erased states, N is a positive integer, and wherein a maximum threshold voltage of a threshold voltage distribution for the second erased state is less than the first verification voltage, and a minimum threshold voltage of the threshold voltage distribution for the second erased state is greater than a maximum threshold voltage of a threshold voltage distribution for a highest programmed state among the 2^{N}-1 non-erased states.

In some examples, a value range for a voltage value of the first verification voltage is 3 V-4 V.

In some examples, the memory device comprises a ferroelectric memory.

In a second aspect, an example of the present disclosure provides an operating method for a memory device, comprising: applying a first verification voltage to a selected word line of the memory device to perform a first verification operation on a plurality of memory cells connected to the selected word line, wherein the plurality of memory cells connected to the selected word line comprise a first group of memory cells and a second group of memory cells, threshold voltages for first memory cells in the first group of memory cells are less than the first verification voltage, and threshold voltages for second memory cells in the second group of memory cells are greater than or equal to the first verification voltage; and performing a program operation on at least a portion of the first memory cells in the first group of memory cells and the second memory cells in the second group of memory cells, to program the at least a portion of the first memory cells and the second memory cells to respective target memory states, wherein threshold voltages corresponding to the target memory states are less than the first verification voltage.

In some examples, the method further comprises: performing an erase operation on a memory block comprising the plurality of memory cells connected to the selected word line prior to the first verification operation, to cause the plurality of memory cells in the memory block to be in a first erased state, wherein the first verification voltage is greater than a minimum threshold voltage of a threshold voltage distribution for the first erased state and less than a maximum threshold voltage of the threshold voltage distribution for the first erased state.

In some examples, the method further comprises: applying a first pass voltage to an unselected word line of the memory device during the first verification operation, wherein the first pass voltage is greater than the maximum threshold voltage of the threshold voltage distribution for the first erased state.

In some examples, the method further comprises: applying a first voltage to a selected bit line of the memory device and applying a second voltage to an unselected bit line of the memory device during the first verification operation, wherein the first voltage is greater than the second voltage.

In some examples, the method further comprises: applying a read voltage to the selected word line and applying a second pass voltage to the unselected word line during a read operation after the program operation, wherein the second pass voltage is greater than or equal to the first verification voltage and less than the first pass voltage.

In some examples, the second pass voltage is less than the maximum threshold voltage of the threshold voltage distribution for the first erased state.

In some examples, the method further comprises: during the program operation, applying a programming voltage to the selected word line connected to the at least a portion of the first memory cells and the second memory cells, and applying a third pass voltage to an unselected word line.

In some examples, the number of bits stored in each of the memory cells is N, the target memory state is one memory state among 2^{N} memory states comprising a second erased state and 2^{N}-1 non-erased states, N is a positive integer, and wherein a maximum threshold voltage of a threshold voltage distribution for the second erased state is less than the first verification voltage, and a minimum threshold voltage of the threshold voltage distribution for the second erased state is greater than a maximum threshold voltage of a threshold voltage distribution for a highest programmed state among the 2^{N}-1 non-erased states.

In some examples, a value range for a voltage value of the first verification voltage is 3 V-4 V.

In some examples, the memory device comprises a ferroelectric memory.

In a third aspect, the example of the present disclosure provides a memory system, comprising at least one memory device according to at least one of any one of the first aspect; and a controller coupled to the memory device and configured to control the memory device.

In the examples of the present disclosure, the first verification operation is added prior to the program operation, wherein the first verification operation is performed on the plurality of memory cells connected to the selected word line by applying the first verification voltage to the selected word line. Also, the plurality of memory cells connected to the selected word line are divided into the first group of memory cells and the second group of memory cells based on the relationship between the threshold voltages for the memory cells and the first verification voltage, wherein the threshold voltages for the first memory cells in the first group of memory cells are less than the first verification voltage, and the threshold voltages for the second memory cells in the second group of memory cells are greater than or equal to the first verification voltage. In a subsequent program operation, at least a portion of the first memory cells and the second memory cells are programmed to respective target memory states, and threshold voltages corresponding to a plurality of target memory states are less than the first verification voltage. According to the example of the present disclosure, the first verification operation is added prior to the program operation, so that at least the second memory cells with the threshold voltages greater than or equal to the first verification voltage are programmed into the target memory state with the threshold voltage smaller than the first verification voltage in the program operation. As such, a narrower final threshold voltage distribution can be obtained after the program operation, which facilitates reduction of the read pass voltage applied to unselected word lines during read operations. Consequently, this technical solution effectively mitigates read disturbance issues while enhancing performance and reliability of memory devices and systems thereof.

### BRIEF DESCRIPTION OF THE DRAWINGS

FIG. 1 is a first schematic diagram of an example system with a memory system provided by an example of the present disclosure;

FIG. 2 is a schematic diagram of an example memory card with a memory system provided by an example of the present disclosure;

FIG. 3 is a schematic diagram of an example solid state drive with a memory system provided by an example of the present disclosure;

FIG. 4 is a schematic diagram of an example memory device includes a peripheral circuit provided by an example of the present disclosure;

FIG. 5 is a schematic cross-sectional diagram of a memory cell array provided by an example of the present disclosure;

FIG. 6 is an example electrical polarization of a ferroelectric layer as a function of applied electric field provided by an example of the present disclosure;

Diagram (a) in FIG. 7 is a schematic diagram of a ferroelectric transistor when an erase operation is performed, diagram (b) in FIG. 7 shows a graph of drain current versus gate voltage when an erase operation is performed, diagram (c) in FIG. 7 is a schematic diagram of a ferroelectric transistor when a program operation is performed, and diagram (d) in FIG. 7 shows a graph of drain current versus gate voltage when a program operation is performed;

FIG. 8 is a schematic diagram of a threshold voltage distribution corresponding to a multi-level cell (MLC) type memory cell provided by an example of the present disclosure;

FIG. 9 is a schematic diagram of an example memory device comprising a memory array and a peripheral circuit provided by an example of the present disclosure;

FIG. 10 is a second schematic diagram of an example system with a memory system provided by an example of the present disclosure;

FIG. 11 is a first voltage timing diagram provided by an example of the present disclosure;

FIG. 12 is a second schematic diagram of a threshold voltage distribution corresponding to an MLC type memory cell provided by an example of the present disclosure;

FIG. 13 is a second voltage timing diagram provided by an example of the present disclosure;

FIG. 14 is a third voltage timing diagram provided by an example of the present disclosure;

FIG. 15 is a schematic diagram of a threshold voltage distribution corresponding to a quad-level cell (QLC) type memory cell provided by an example of the present disclosure;

FIG. 16 is a schematic flowchart of an operating method for a memory device provided by an example of the present disclosure.

### DETAILED DESCRIPTION

Examples disclosed by the present disclosure will be described in more detail below with reference to the accompanying drawings. While examples of the present disclosure are shown in the drawings, it should be understood that the disclosure may be implemented in various forms and should not be limited by the DETAILED DESCRIPTION set forth herein. Rather, these examples are provided to enable a more thorough understanding of the present disclosure and to fully convey the scope of the disclosure to those skilled in the art.

In the following description, numerous specific details are given in order to provide a more thorough understanding of the present disclosure. It will be apparent to those skilled in the art, however, that the present disclosure may be practiced without one or more of these details. In other examples, to avoid confusion with the present disclosure, some technical features well-known in the art are not described, that is, not all features of the actual examples are described herein, and well-known functions and structures are not described in detail.

In the drawings, like reference numerals refer to like elements throughout.

It should be understood that spatial relation terms such as “under”, “below”, “lower”, “beneath”, “over”, “above”, and the like, may be used herein for ease of description to describe the relationship between one element or feature and other elements or features shown in the figures. It should be appreciated that in addition to the orientations shown in the figures, the spatial relation term intent also includes different orientations of the devices in use and operation. For example, if the devices in the figures are flipped, then the element or feature described as “below” or “under” or “beneath” the other elements will be oriented “on” the other elements or features. Thus, the example terms “below” and “under” may include both upper and lower orientations. The devices may be additionally oriented (rotated 90 degrees or at other orientations) and the spatial description terminology used herein is interpreted accordingly.

The terminology used herein is for the purpose of describing particular examples only and is not intended as a limitation of the present disclosure. As used herein, the singular forms “a,” “an,” and “the” are intended to include plural forms as well, unless the context clearly indicates otherwise. It should also be understood that at least one of the terms “comprise” or “include”, when used in this specification, identify the presence of at least one of the stated features, integers, operations, elements, or components, but do not preclude the presence or addition of at least one of one or more other features, integers, operations, elements, components, or groups. As used herein, the term “at least one of . . . or . . . ” includes any and all combinations of related listed items.

NAND-type memories, while excelling in storage density, production costs, and program/erase speed, still exhibit limitations in certain application scenarios. For instance, NAND-type memories demonstrate relatively lower read/write speeds and endurance, their erase operations require significant energy consumption and time, which restricts their application in scenarios demanding high real-time requirements and reliability. In contrast, ferroelectric random access memory (FeRAM), as an emerging non-volatile memory technology, offers superior read/write speeds, enhanced endurance, and lower power consumption.

Based on industry research, incorporating ferroelectric materials into three-dimensional NAND-type memories can improve reliability of the memory devices and facilitate further scaling of the memory devices. In some examples, a ferroelectric layer can be positioned between a gate layer and a channel layer to form ferroelectric transistors, thereby creating three-dimensional NAND-type ferroelectric memories (3D FeNAND). This novel memory not only retains the advantages of high density and low cost, but also integrates the high-speed operation, low power consumption, and superior endurance characteristics of FeRAM. It thereby delivers enhanced performance, broader application scenarios, and meets the increasing demands for speed, power consumption, and reliability in future storage technologies.

Hereinafter, the memory system provided by the present disclosure will be described by taking a memory system comprising a three-dimensional NAND-type ferroelectric memory as an example.

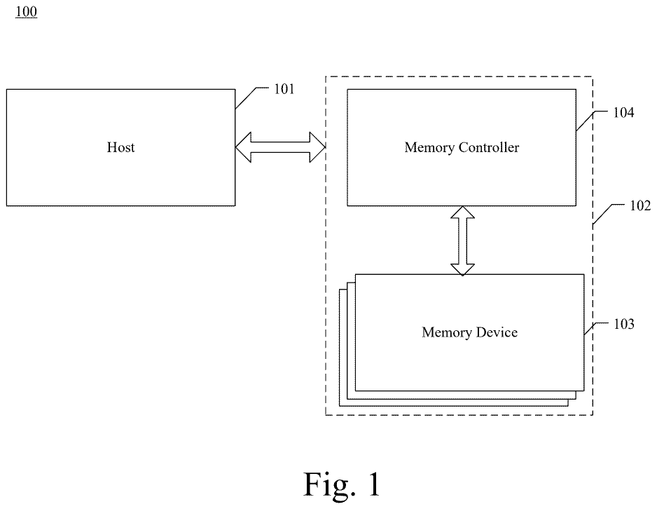

FIG. 1 is a schematic diagram of an example system with a memory system provided by an example of the present disclosure. In an example of the present disclosure, the system 100 may comprise a mobile phone, a desktop computer, a laptop computer, a tablet computer, a vehicle computer, a game console, a printer, a positioning device, a wearable electronic device, a smart sensor, a Virtual Reality (VR) device, an Augmented Reality (AR) device, or any other suitable electronic device with a memory therein. As shown in FIG. 1, the system 100 may include a host 101 and a memory system 102, which may include one or more memory devices 103 and a memory controller 104. The host 101 may include a processor of an electronic device, for example, a Central Processing Unit (CPU), or a System on a Chip (SoC), for example, an Application Processor (AP). The host 101 may be configured to send or receive data to or from the memory system 102.

In some examples, the memory controller 104 is coupled to the memory device 103 and the host 101 and is configured to control the memory device 103. The memory controller 104 may manage data stored in the memory device 103 and communicate with the host 101. In some examples, the memory controller 104 is designed to operate in a low duty cycle environment, such as in a secure digital card, Compact Flash Card (CFC), Universal Serial Bus (USB) flash drive, or other medium for use in electronic devices such as personal computers, digital cameras, mobile phones, and the like. In other examples, the memory controller 104 is designed to operate in a high duty cycle environment, such as a solid state disk or Embedded Multi-Media Card (eMMC).

In some examples, the memory controller 104 and the one or more memory devices 103 may be integrated into various types of storage devices, that is, the memory system 102 may be implemented and packaged into different types of terminal electronics.

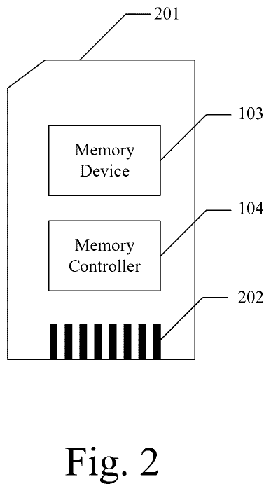

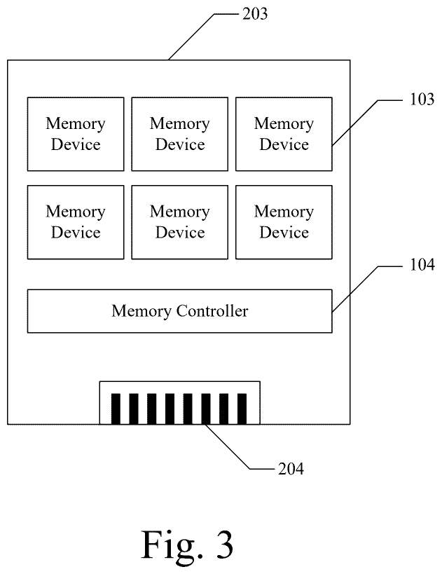

In one example as shown in FIG. 2, the memory controller 104 and a single memory device 103 may be integrated into a memory card 201. The memory card 201 may comprise one of a compact flash memory card, a Smart Media Card (SMC), a Memory Stick (MS), a Multi-Media Card (MMC), for example, an RS-MMC, an MMCmicro, an eMMC, or the like, a secure digital card, for example, a Mini SD card, a Micro SD card, an SDHC card, or the like, and a universal flash memory card. The memory card 201 may also include a memory card connector 202 that couples the memory card 201 with a host end device (e.g., host 101 in FIG. 1). In another example as shown in FIG. 3, the memory controller 104 and a plurality of memory devices 103 may be integrated into an SSD203. The SSD203 may also include an SSD connector 204 that couples the SSD203 with a host end device (e.g., host 101 in FIG. 1). In some examples, at least one of the storage capacity or operating speed of SSD203 is greater than of the memory card 201.

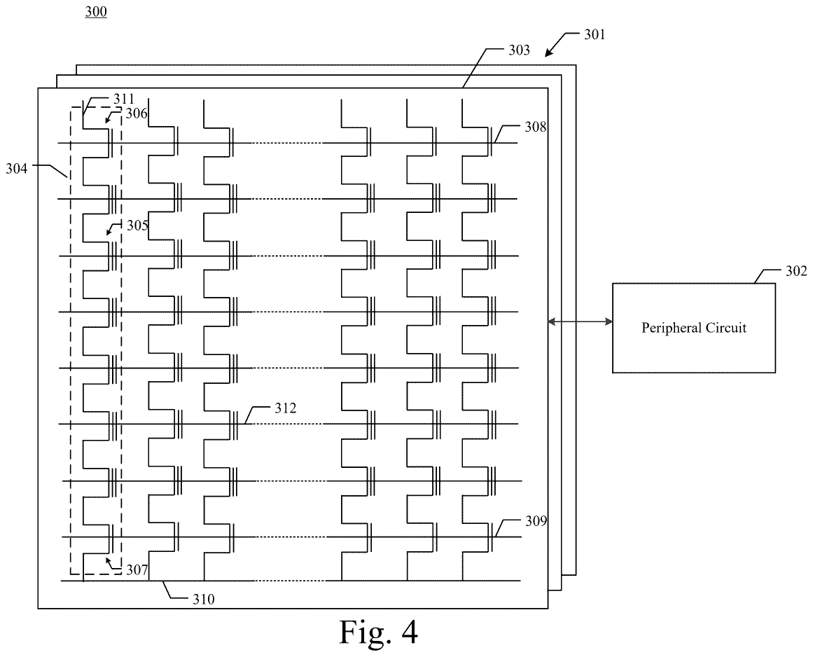

FIG. 4 is a schematic circuit diagram of an example memory device 300 comprising a peripheral circuit provided by an example of the present disclosure. The memory device 300 may be an example of the memory device 103 in FIG. 1. The memory device 300 may include a memory cell array 301 and a peripheral circuit 302 coupled to the memory cell array 301. Taking the memory cell array 301 as a three-dimensional NAND-type ferroelectric memory cell array as an example for description, the memory cell 305 is a NAND ferroelectric memory cell, and is provided in the form of an array of memory cell strings 304, wherein each memory cell string 304 extends vertically above a substrate (not shown). In some examples, each memory cell string 304 includes a plurality of memory cells 305 coupled in series and stacked vertically.

As shown in FIG. 4, each memory cell string 304 may include a Bottom Select Transistor (BST) 307 at its source terminal and a Top Select Transistor (TST) 306 at its drain terminal. The bottom select transistor 307 and the top select transistor 306 may be configured to activate a selected memory cell string 304 during read and program operations. In some examples, the sources of the memory cell strings 304 in the same memory block 303 may be coupled through a Common Source Line (CSL) 310. In other words, all the memory cell strings 304 in the same memory block 303 have an Array Common Source (ACS). According to some examples, the top select transistor 306 of each memory cell string 304 is coupled to a respective Bit Line (BL) 311, from which data may read or write data via an output bus (not shown). In some examples, each memory cell string 304 is configured to be selected or deselected by at least one of applying a select voltage (e.g., a voltage higher than a threshold voltage of the top select transistor 306) or a deselect voltage (e.g., 0V) to a top select gate (TSG) of the corresponding top select transistor 306 through one or more top select lines (TSL) 308 or applying a select voltage (e.g., a voltage higher than a threshold voltage of the bottom select transistor 307) or a deselect voltage (e.g., 0V) to a bottom select gate (BSG) of the corresponding bottom select transistor 307 through one or more bottom select lines (BSL) 309.

As shown in FIG. 4, the memory cell strings 304 can be organized into a plurality of memory blocks 303, each of which can have a common source line 310. In some examples, each memory block 303 is a basic data unit for an erase operation, i.e., all memory cells 305 on the same memory block 303 are erased at the same time. To erase the memory cells 305 in the selected memory block, a common source line 310 coupled to the selected memory block and unselected memory blocks in the same plane as the selected memory block may be biased with an erase voltage. It should be understood that in some examples, the erase operation may be performed at a half-memory block level, at a quarter-memory block level, or at a level having any suitable number of memory blocks or any suitable fractions of a memory block. The memory cells 305 of adjacent memory cell strings 304 may be coupled via word lines 312, which select which row of memory cells 305 is affected by read or program operations.

In some examples, the peripheral circuit 302 may comprise any suitable analog, digital, and mixed-signal circuits for enabling the operations of the memory cell array 301 by applying and sensing at least one of voltage signals or current signals to and from each target memory cell through bit lines 311, word lines 312, common source lines 310, bottom select lines 309, and top select lines 308. The peripheral circuit 302 may comprise various types of peripheral circuits formed using metal-oxide-semiconductor technology.

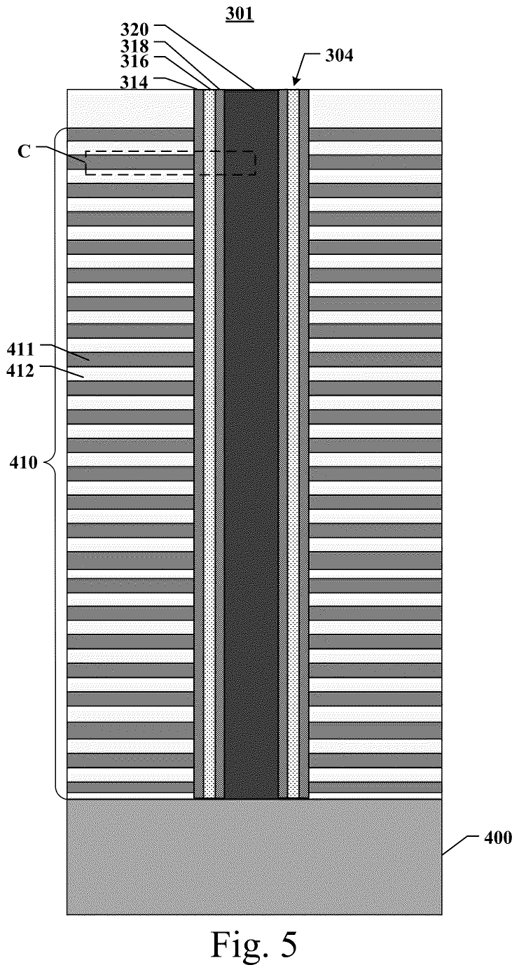

FIG. 5 is a schematic cross-sectional diagram of an example memory cell array comprising a memory string provided by an example of the present disclosure. As shown in FIG. 5, the memory cell array 301 may include a stacked structure 410 comprising a plurality of gate layers 411 and a plurality of insulating layers 412 stacked alternately in sequence, and a channel structure vertically penetrating the gate layers 411 and the insulating layers 412, wherein the channel structure is coupled to each of the gate layers to form a memory cell, and the channel structure is coupled to the plurality of gate layers in the stacked structure 410 to form a memory cell string 304. The gate layers 411 and the insulating layers 412 may be alternately stacked, and two adjacent gate layers 411 are separated by one insulating layer 412.

The composition material of the gate layer 411 may include conductive material. The conductive material includes, but is not limited to, tungsten (W), cobalt (Co), copper (Cu), aluminum (Al), polysilicon, doped silicon, silicide, or any combination thereof. In some examples, each gate layer 411 includes a metal layer, such as a tungsten layer. In some examples, each gate layer 411 includes a doped polysilicon layer. Each gate layer 411 may include a control gate surrounding the memory cell. The gate layer 411 at the top of the stacked structure 410 may extend laterally as an upper select gate line, the gate layer 411 at the bottom of the stacked structure 410 may extend laterally as a lower select gate line, and the gate layers 411 extending laterally between the upper select gate line and the lower select gate line may function as word line layers.

In some examples, the stacked structure 410 may be disposed on a substrate 400. The substrate 400 may include silicon (e.g., monocrystalline silicon), silicon germanium (SiGe), gallium arsenide (GaAs), germanium (Ge), silicon-on-insulator (SOI), germanium-on-insulator (GOI), or any other suitable material.

In some examples, the memory cell string 304 includes a channel structure that extends vertically through the stacked structure 410. In some examples, the channel structure includes a semiconductor channel layer 320, an interface layer 318, a storage layer 316, and a blocking layer 314. The channel structure may have a cylindrical shape (e.g., pillar shape), in which the semiconductor channel layer 320, the interface layer 318, the storage layer 316 and the blocking layer 314 are arranged radially from the center of the pillar toward the outer surface of the pillar, according to some examples.

In some examples, the semiconductor channel layer 320 includes silicon, e.g., polysilicon. The interface layer 318 may include silicon oxide, silicon oxynitride, or any combination thereof. The storage layer 316 includes a ferroelectric layer, the material of the ferroelectric layer includes, but is not limited to, Hf_{0.5}Zr_{0.5}O₂ material or doped hafnium oxide material, wherein the doping elements include Zr, Y, Al, Gd and Si. The blocking layer 314 may include silicon oxide, silicon oxynitride, a high dielectric constant (high-k) dielectric, or any combination thereof.

In some examples, the blocking layer 314 is located between the gate layer 411 and the storage layer 316, which may block the interaction between the ferroelectric layer of the storage layer 316 and the gate layer 411, and improve the performance of the device.

In other examples, the channel structure may further include an oxide insulating layer, a semiconductor channel layer and a storage layer sequentially disposed from inside to outside, wherein the material of the storage layer includes, but is not limited to, Hf_{0.5}Zr_{0.5}O₂ material or doped hafnium oxide material.

As shown in FIG. 5, the semiconductor channel layer 320, the gate layer 411, the blocking layer 314, the storage layer 316 and the interface layer 318 collectively form a ferroelectric transistor, that is, a memory cell C. The information stored in the memory cell C depends on the polarization direction of the ferroelectric layer in the storage layer 316. It can be understood that the memory cell C includes the gate layer 411, a portion of the blocking layer 314 corresponding to the gate layer 411, a portion of the storage layer 316, a portion of the interface layer 318 and a portion of the semiconductor channel layer 320.

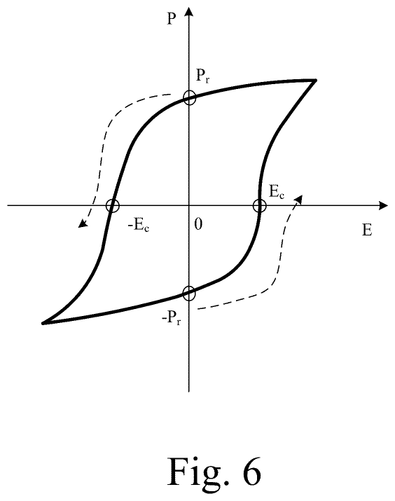

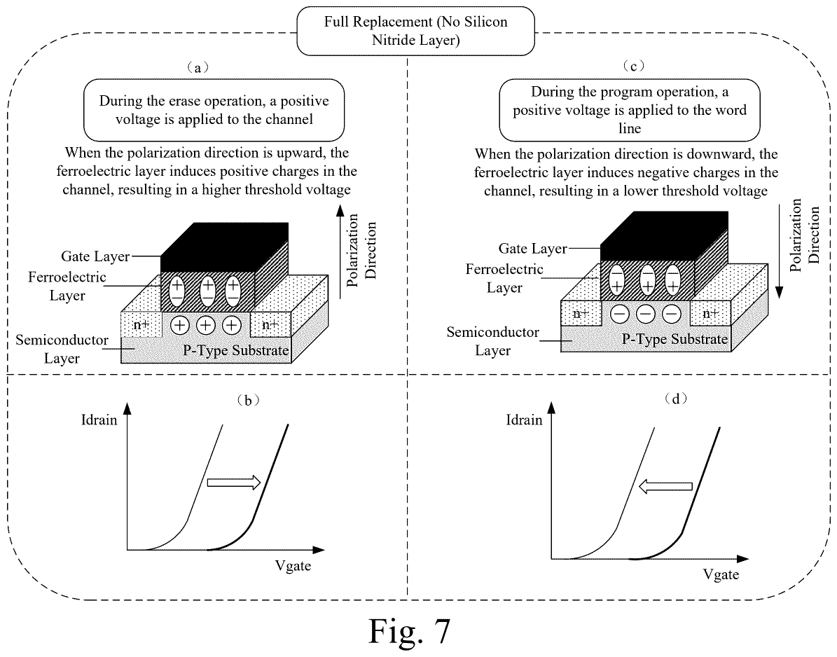

The changes in the ferroelectric layer during the application and removal of an external electric field are briefly described below with reference to FIG. 6. FIG. 6 illustrates example electric polarization P of the ferroelectric layer as a function of the applied electric field E, wherein the remaining polarization Pr (or the reverse remaining polarization −Pr) of the ferroelectric layer may be measured under a zero external electric field. As shown in FIG. 6, the variation of electric polarization with the applied electric field follows a hysteresis loop. When a positive electric field is applied to the ferroelectric layer, the layer becomes positively polarized until its electric polarization P changes linearly with the applied electric field E.

When the external electric field is removed, the electric polarization (also referred to as polarization in the present disclosure) in the ferroelectric layer does not vanish. After the ferroelectric layer is fully polarized and the external electric field is removed, the remaining polarization in the ferroelectric layer is the remaining polarization Pr.

Applying a reverse electric field does not depolarize the ferroelectric layer until it reaches the reverse coercive field −Ec. Here, the negative sign indicates the reverse direction of the electric field, and the magnitude is denoted by Ec, wherein the polarization P reaches zero on the left side of the loop. As the magnitude of the negative electric field continues to increase, the ferroelectric layer becomes fully polarized in the negative direction. When the negative electric field is removed, the ferroelectric layer retains a reverse remaining polarization −Pr in the negative direction.

Starting from this point, applying a positive electric field and reaching the coercive field Ec in the positive direction, the polarization in the ferroelectric layer can flip again to the positive direction until it becomes fully polarized and follows the electric field linearly. The hysteresis loop can be repeated multiple times to alter the electric polarization direction in the ferroelectric layer. Different spontaneous polarization directions in the ferroelectric layer may represent stored “0” or “1”.

Referring to FIG. (a) and FIG. (b) of FIG. 7, wherein FIG. (a) of FIG. 7 is a schematic diagram of a ferroelectric transistor when an erase operation is performed, and FIG. (b) in FIG. 7 shows a graph of drain current (Idrain) versus gate voltage (Vgate) when an erase operation is performed. As shown in FIG. (a) of FIG. 7, the ferroelectric transistor may include: a source and a drain disposed in the semiconductor layer; a ferroelectric layer disposed on the semiconductor layer; and a gate layer disposed on the ferroelectric layer. The semiconductor layer may include a p-type substrate, wherein the source and drain are formed by doping the semiconductor layer and may be n-type doped regions, and the gate layer may include a metal gate layer, for example. During the erase operation, a positive voltage is applied to the channel of the ferroelectric transistor. When the polarization direction of the ferroelectric layer is upward, positive charges are induced in the channel, resulting in a higher threshold voltage of the ferroelectric transistor. As indicated by the arrow in FIG. (b) in FIG. 7, the threshold voltage of the ferroelectric transistor increases after the erase operation is performed.

Referring to FIG. (c) and FIG. (d) in FIG. 7, wherein FIG. (c) in FIG. 7 is a schematic diagram of a ferroelectric transistor when a program operation is performed, and FIG. (d) in FIG. 7 shows a graph of drain current (Idrain) versus gate voltage (Vgate) when a program operation is performed. As shown in FIG. 7 (c), the structure of the ferroelectric transistor may refer to the related description of FIG. (a) of FIG. 7, and details are not described herein again. During the program operation, a positive voltage is applied to the gate layer of the ferroelectric transistor. When the polarization direction of the ferroelectric layer is downward, negative charges are induced in the channel, resulting in a lower threshold voltage of the ferroelectric transistor. As indicated by the arrow in FIG. (d) in FIG. 7, the threshold voltage of the ferroelectric transistor decreases after the program operation is performed.

It should be noted that the ferroelectric transistor shown in FIG. 7 is a simplified schematic diagram of the ferroelectric transistor in FIG. 5, and for brevity, the interface layer and the blocking layer are not shown in FIG. 7.

In some examples, each memory cell is a Single Level Cell (SLC) having two possible memory states and thus may store one bit of data. For example, the first memory state may correspond to a first voltage range and the second memory state may correspond to a second voltage range.

In some examples, the ferroelectric layer can not only store “0” or “1” based on different polarization directions but also achieve multi-bit storage based on varying polarization degrees. For instance, by adjusting the magnitude of the applied voltage to change the polarization intensity of the ferroelectric layer, different information can be stored under different polarization states to realize multi-bit storage. For example, each memory cell may be a multi-level cell capable of storing more than one bit of data in four or more memory states, such as a Multi-Level Cell (MLC) storing two bits per cell, a Triple Level Cell (TLC) storing three bits per cell, or a Quad-Level Cell (QLC) storing four bits per cell.

It should be noted that the memory states mentioned here correspond to the storage states of the memory cells as described in the present disclosure. Different types of memory cells have varying numbers of storage states. For example, SLC-type memory cells have two storage states (i.e., one programmed state and one erased state). MLC-type memory cells have four storage states (i.e., one erased state and three programmed states). TLC-type memory cells have eight storage states (i.e., one erased state and seven programmed states). In some examples, QLC-type memory cells have sixteen storage states (i.e., one erased state and fifteen programmed states).

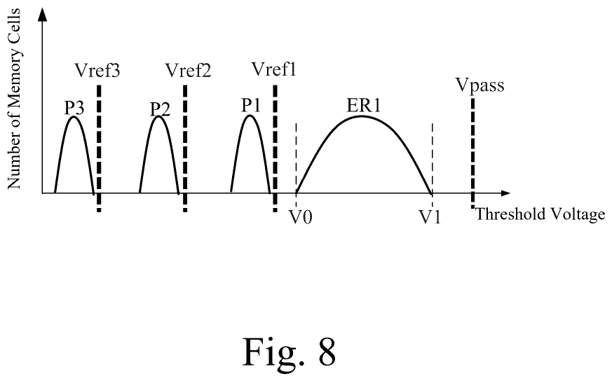

For example, as shown in FIG. 8, in the MLC mode, the number of bits stored in the memory cell is 2 and thus the memory cell has 4 memory states. Referring to FIG. 8, the 4 memory states include 1 erased states and 3 non-erased states, and each memory state may correspond to a specific range of the threshold voltage. In some examples, the 4 memory states are a first erased state ER1, a first memory state (also referred to as a first programmed state) P1, a second memory state (also referred to as a second programmed state) P2, and a third memory state (also referred to as a third programmed state) P3. The threshold voltage for the memory cell in the first erased state is greater than the threshold voltage for the memory cell in the non-erased states. As shown in FIG. 8, the threshold voltage for the memory cell in the first erased state ER1 is greater than the threshold voltage for the memory cell in the first memory state P1, in the second memory state P2, or in the third memory state P3.

For example, as shown in FIG. 8, a distribution of threshold voltages corresponding to the first erased state ER1 is wider.

In some examples, after a program operation, 4 memory states (ER1 and P1-P3) may be verified during a program verify operation using one or more program verify voltages Vref1, Vref2, and Vref3. By applying one or more of the program verify voltages Vref1, Vref2, and Vref3 to the control gate of a target memory cell, the range of the threshold voltage Vth for the target memory cell can be determined. For example, to verify whether a memory cell is in the third memory state P3, the program verify voltage Vref3 may be used. If the target memory cell is in the third memory state P3, the threshold voltage Vth for the target memory cell is lower than the program verify voltage Vref3, causing the target memory cell to be turned on and form a conductive path in the channel. If the target memory cell is in either of the second memory state P2, the first memory state P1, or the first erased state ER1, the threshold voltage Vth for the target memory cell is higher than the program verify voltage Vref3, causing the target memory cell to be switched off. The memory state or threshold voltage for the target memory cell can be verified by measuring or sensing the current through the target memory cell via the page buffer/sense amplifier at the corresponding bit line.

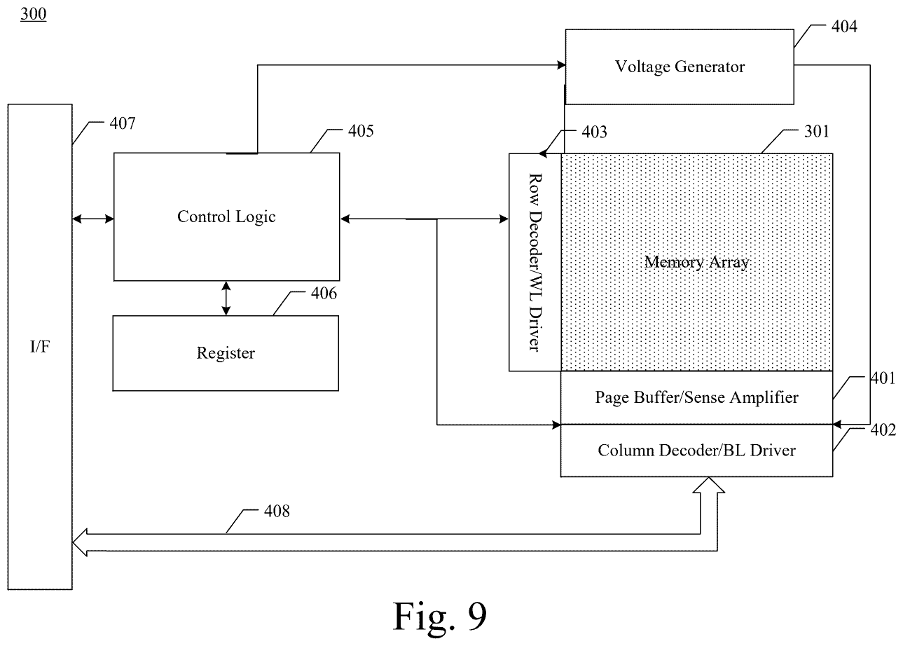

FIG. 9 shows some example peripheral circuits, and the peripheral circuit comprises a page buffer/sense amplifier 401, a column decoder/bit line driver 402, a row decoder/word line driver 403, a voltage generator 404, a control logic 405, a register 406, a flash memory interface 407, and a data bus 408. It should be understood that in some examples, additional peripheral circuits not shown in FIG. 5 may also be comprised.

The page buffer/sense amplifier 401 can be configured to read data from the memory cell array 301 and program (write) data to the memory cell array 301 according to a control signal from the control logic 405. In one example, the page buffer/sense amplifier 401 can store a page of program data (write data) to be programmed into the memory cell array 301. In another example, the page buffer/sense amplifier 401 can perform a program verify operation to ensure that the data has been correctly programmed into the memory cells coupled to the selected word line. In yet another example, the page buffer/sense amplifier 401 can also sense the low power signals from the bit line that represent data bits stored in the memory cells and amplify the small voltage swing to recognizable logic levels in a read operation. The column decoder/bit line driver 402 can be configured to be controlled by the control logic 405 and select one or more memory cell strings 308 by applying bit line voltages generated from the voltage generator 404.

The row decoder/word line driver 403 can be configured to be controlled by the control logic 405 and select/deselect memory blocks of the memory cell array 301 and select/deselect word lines of memory blocks. The row decoder/word line driver 403 can be further configured to drive word lines using word line voltages generated from the voltage generator 404. In some examples, the row decoder/word line driver 403 can also select/deselect and drive bottom select lines and top select lines as well. As described below in detail, the row decoder/word line driver 403 is configured to perform program operations on the memory cells coupled to the selected word line(s). The voltage generator 404 can be configured to be controlled by the control logic 405 and generate the word line voltages (e.g., read voltages, program voltages, pass voltages, local voltages, verification voltages, etc.), bit line voltages, and source line voltages to be supplied to the memory cell array 301.

The control logic 405 may be coupled to each peripheral circuit described above and configured to control the operation of each peripheral circuit. The register 406 can be coupled to the control logic 405 and include status registers, command registers, and address registers for storing status information, command operation codes (OP codes), and command addresses for controlling the operations of each peripheral circuit. The flash memory interface 407 may be coupled to the control logic 405 and act as a control buffer to buffer and relay control commands received from a host-side device (not shown) to the control logic 405, and to buffer and relay status information received from the control logic 405 to the memory controller. The flash memory interface 407 may further be coupled to the column decoder/bit line driver 402 via the data bus 408 and act as a data I/O interface and data buffer to buffer and relay data to or from the memory cell array 301.

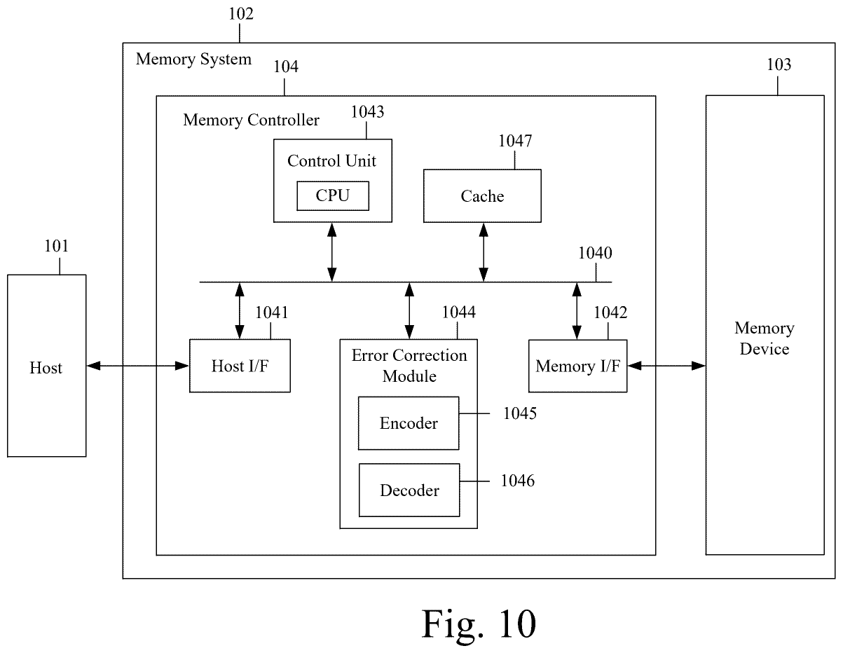

FIG. 10 is a schematic diagram of a system comprising a host and a memory system provided by an example of the present disclosure. As shown in FIG. 10, a memory system 102 is connected to a host 101, wherein the memory system 102 may comprise: a memory controller 104 and a memory device 103, wherein the memory controller 104 is configured to control the memory device 103 to perform operations such as read, write, and erase, and the memory controller 104 and the memory device 103 may also be coupled in any suitable manner. The memory controller 104 may comprise a host interface (I/F) 1041, a memory interface (I/F) 1042, a control unit 1043, an error correcting module 1044, a cache 1047, and a bus 1040. Among them, the host interface 1041 is a connection interface between the host 101 and the memory controller 104, and the host interface 1041 allows the host 101 and the memory controller 104 to communicate according to a specific protocol, send read and write requests, and perform other operations. The memory interface 1042 is a connection interface between the memory controller 104 and the memory device 103, and the memory interface 1042 is configured to enable data transmission between the memory controller 104 and the memory device 103. The control unit 1043 is configured to control the memory system 102 as a whole.

In some specific examples, the control unit 1043 may comprise one or more units with logical operation capabilities, such as at least one of a central processing unit (CPU) or a microcontroller unit (MCU).

In some specific examples, the cache 1047 is configured to cache data, and may be a volatile memory device with a relatively fast read and write speed, such as at least one of a static random access memory (SRAM) or a dynamic random access memory (DRAM).

In some specific examples, the error correcting module 1044 may be configured to encode and decode data in the memory system using error correcting code technology. In some examples, the error correcting module 1044 may comprise an encoder 1045 and a decoder 1046, wherein the encoder 1045 may be configured to: encode data to be written into the memory device in a write operation, and the decoder 1046 may be configured to: decode a codeword to be decoded in read data in a read operation.

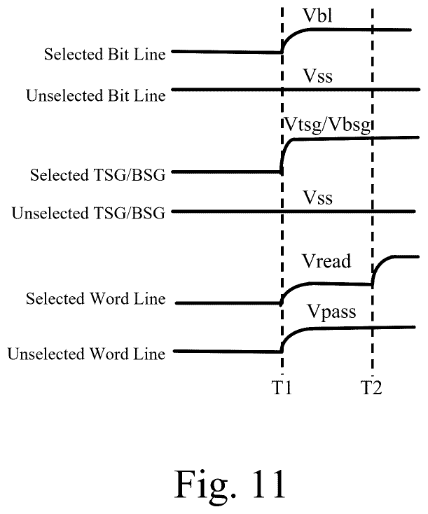

In the above example, when a read operation is performed on the MLC-type memory cell, as shown in FIG. 11, at a first point of time T1, a read pass voltage Vpass is applied to an unselected word line, and a read voltage Vread is applied to a selected word line. A voltage Vbl is applied to a selected bit line, a ground voltage Vss is applied to an unselected bit line. A select voltage Vtsg/Vbsg is applied to the selected TSG and the selected BSG, and a ground voltage Vss is applied to the unselected TSG and the unselected BSG. For example, the read voltage Vread may be, for example, 0V, the voltage Vbl may be, for example, 2V, the ground voltage Vss may be, for example, 0V, the select voltage Vtsg/Vbsg is higher than the threshold voltage of the top select transistor and the bottom select transistor, and the select voltage Vtsg/Vbsg may be, for example, the power supply voltage Vcc.

It should be noted that, applying a read voltage to a selected word line at a certain point of time does not mean the selected word line can reach the read voltage at that point of time. In other words, when a read voltage is applied to the selected word line at a certain point of time, this point of time serves as the starting point of time for the voltage of the selected word line to begin ramping up. After undergoing a voltage settling period, the voltage of the selected word line reaches the read voltage.

In some examples, the voltage settling period for the selected word line is greater than the time interval between the first point of time T1 and the second point of time T2 shown in FIG. 11.

In other examples, the time interval between the first point of time T1 and the second point of time T2 is the voltage settling period.

In some examples, as shown in FIG. 8 and FIG. 11, during the read operation on the target memory cell among multiple memory cells, the read pass voltage Vpass applied to the unselected word line exceeds the maximum threshold voltage for all memory cells. This ensures that all memory cells on the selected memory string, except the target memory cell, can be fully turned on.

In some examples, the threshold voltage distribution for the first erased state ER1 has a minimum threshold voltage V0 and a maximum threshold voltage V1, wherein the maximum threshold voltage V1 of the threshold voltage distribution for the first erased state ER1 is the maximum threshold voltage for all the memory cells. For example, the read pass voltage Vpass is greater than the maximum threshold voltage V1 of the threshold voltage distribution for the first erased state ER1. Since the read pass voltage Vpass applied during read operations induces a weak programming effect on unread memory cells, an excessively wide threshold voltage distribution for the first erase state ER1 would cause the read pass voltage Vpass to be too high and the weak programming effect to be more significant, thus leading to significant read disturb after multiple read operations. Consequently, threshold voltage drift may occur in unread memory cells, altering their memory states and resulting in read errors.

In this regard, the present disclosure provides the following examples.

An example of the present disclosure provides a memory device, as shown in FIG. 4, wherein the memory device 300 comprises: a memory cell array 301 comprising a plurality of memory cells 305; a plurality of word lines 312 coupled to the memory cell array 301; and a peripheral circuit 302 coupled to the memory cell array 301 and configured to: apply a first verification voltage to a selected word line to perform a first verification operation on a plurality of memory cells 305 connected to the selected word line, wherein the plurality of memory cells 305 connected to the selected word line comprise a first group of memory cells and a second group of memory cells, threshold voltages for first memory cells in the first group of memory cells are less than the first verification voltage, and threshold voltages for second memory cells in the second group of memory cells are greater than or equal to the first verification voltage; and perform a program operation on at least a portion of the first memory cells in the first group of memory cells and the second memory cells in the second group of memory cells, to program the at least a portion of the first memory cells and the second memory cells to respective target memory states, wherein threshold voltages corresponding to the target memory states are less than the first verification voltage.

In the examples of the present disclosure, the first verification operation is added prior to the program operation, wherein the first verification operation is performed on the plurality of memory cells connected to the selected word line by applying the first verification voltage to the selected word line. Also, the plurality of memory cells connected to the selected word line are divided into the first group of memory cells and the second group of memory cells based on the relationship between the threshold voltages for the memory cells and the first verification voltage, wherein the threshold voltages for the first memory cells in the first group of memory cells are less than the first verification voltage, and the threshold voltages for the second memory cells in the second group of memory cells are greater than or equal to the first verification voltage. In a subsequent program operation, at least a portion of the first memory cells and the second memory cells are programmed to respective target memory states, and threshold voltages corresponding to a plurality of target memory states are less than the first verification voltage. According to the example of the present disclosure, the first verification operation is added prior to the program operation, so that at least the second memory cells with the threshold voltages greater than or equal to the first verification voltage are programmed into the target memory state with the threshold voltage smaller than the first verification voltage in the program operation. As such, a narrower final threshold voltage distribution can be obtained after the program operation, which facilitates reduction of the read pass voltage applied to unselected word lines during read operations. Consequently, this technical solution effectively mitigates read disturbance issues while enhancing performance and reliability of memory devices and systems thereof.

In some examples, the peripheral circuit is further configured to perform an erase operation on a memory block comprising the plurality of memory cells connected to the selected word line prior to the first verification operation, to cause all the plurality of memory cells in the memory block to be in a first erased state, wherein the first verification voltage is greater than a minimum threshold voltage of a threshold voltage distribution for the first erased state and less than a maximum threshold voltage of the threshold voltage distribution for the first erased state.

In some examples, during an erase operation, an Incremental Step Pulse Erase (ISPE) method may be employed for three-dimensional NAND-type ferroelectric memory for erasing. That is, both the initial pulse and step increment (ISPE step) of the erase operation are fixed, with the voltage of erase pulses being progressively increased by a step increment. An erase verify operation is performed after each erase pulse.

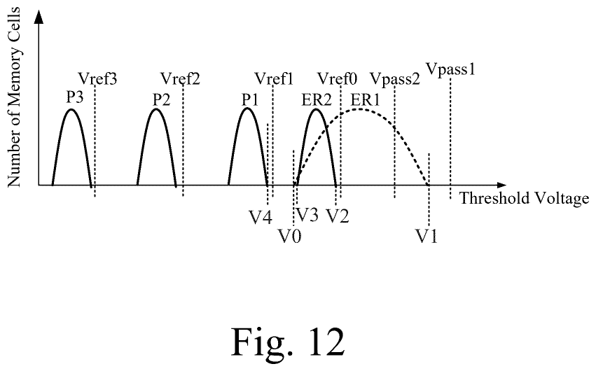

In some examples, after the erase operation, the plurality of memory cells in the memory block are all in the first erased state ER1 shown in FIG. 12. Here, the first erased state ER1 may be understood with reference to the detailed description of FIG. 8, and details are not described herein again for brevity.

In some examples, the peripheral circuit 302 is configured to apply a first pass voltage to an unselected word line during the first verification operation, wherein the first pass voltage is greater than the maximum threshold voltage of the threshold voltage distribution for the first erased state.

In some examples, as shown in FIG. 4, the memory device 300 further comprises a plurality of bit lines 311 coupled to the memory cell array 301, wherein the peripheral circuit 302 is configured to: apply a first voltage to a selected bit line and apply a second voltage to an unselected bit line during the first verification operation, wherein the first voltage is greater than the second voltage.

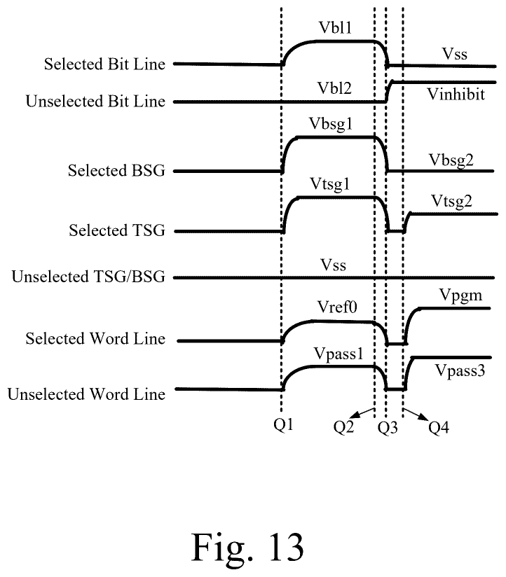

The process of the first verification operation is described in detail below with reference to FIG. 12 and FIG. 13.

As shown in FIG. 12 and FIG. 13, at a first point of time Q1 during a first verification operation (between the first point of time Q1 and a second point of time Q2 shown in FIG. 13), a first verification voltage Vref0 is applied to the selected word line, a first pass voltage Vpass1 is applied to the unselected word line, a first voltage Vbl1 is applied to the selected bit line, a second voltage Vbl2 is applied to the unselected bit line, a first select voltage Vbsg 1 is applied to the selected BSG, a second select voltage Vstg1 is applied to the selected TSG, and a ground voltage Vss is applied to the unselected TSG and the unselected BSG.

It should be noted that, during the first verification operation, the selected word line, the unselected word line, the selected bit line and the unselected bit line are used to facilitate distinguishing different operations during the first verification operation process, and do not indicate that there are two different types of word lines or two different types of bit lines. In practical applications, the selected word line may be any word line coupled in the memory cell array, the selected bit line may be any bit line coupled in the memory cell array, the selected word line corresponding to different first verification operations may be the same word line or different word lines, and the selected bit line may be the same bit line or different bit lines.

In some examples, the first verification voltage Vref0 is greater than the minimum threshold voltage V0 of the threshold voltage distribution for the first erased state ER1 and less than the maximum threshold voltage V1 of the threshold voltage distribution for the first erased state ER1.

In some examples, a value range for a voltage value of the first verification voltage is 3 V-4 V. For example, the value of the voltage value of the first verification voltage may comprise 3 V, 3.25 V, 3.5 V or 4 V.

In some examples, the first pass voltage Vpass1 is greater than the maximum threshold voltage V1 of the threshold voltage distribution for the first erased state ER1.

In some examples, the first voltage Vbl1 is greater than the second voltage Vbl2. For example, the voltage value of the first voltage Vbl1 may be 2 V, the voltage of the second voltage Vbl2 may be the ground voltage Vss, and the ground voltage Vss may be, for example, 0 V.

In some examples, the first select voltage Vbsg1 is greater than the threshold voltage of the bottom select transistor, and the second select voltage Vstg1 is greater than the threshold voltage of the top select transistor.

Through the above process, a first verification operation is performed on the plurality of memory cells 305 connected to the selected word line, thereby dividing the plurality of memory cells 305 connected to the selected word line into a first group of memory cells and a second group of memory cells, wherein threshold voltages for first memory cells in the first group of memory cells are less than the first verification voltage, and threshold voltages for second memory cells in the second group of memory cells are greater than or equal to the first verification voltage.

As shown in FIG. 12, after the first verification operation, the plurality of memory cells connected to the selected word line that are in the first erased state ER1 are further divided into a first group of memory cells in a second erased state ER2 and a second group of memory cells remaining in the first erased state ER1. Here, the maximum threshold voltage V2 of the threshold voltage distribution for the second erased state ER2 is less than the first verification voltage Vref0, and the minimum threshold voltage V3 of the threshold voltage distribution for the second erased state is greater than the maximum threshold voltage V4 of the threshold voltage distribution for the highest programmed state (P1) among three non-erased states (P1, P2, and P3).

In some examples, after the first verification operation, the program operation is performed on at least a portion of the first memory cells in the first group of memory cells and the second memory cells in the second group of memory cells, to program the at least a portion of the first memory cells and the second memory cells to respective target memory states, wherein threshold voltages corresponding to the target memory states are less than the first verification voltage.

In some examples, the peripheral circuit 302 is configured to: during the program operation, apply a programming voltage to the selected word line connected to the at least a portion of the first memory cells and the second memory cells, and apply a third pass voltage to an unselected word line.

The program operation will be described in detail with reference to FIG. 12 and FIG. 13.

In some examples, at the second point of time Q2 shown in FIG. 13, the first verification operation ends, and the selected word line, the unselected word line, the selected bit line, the selected BSG and the selected TSG start to discharge.

As shown in FIG. 12 and FIG. 13, at a third point of time Q3 after the first verification operation (between the third point of time Q3 and a fourth point of time Q4 shown in FIG. 13) during the program operation, the ground voltage Vss is applied to the selected bit line and a program inhibit voltage Vinhibit is applied to the unselected bit line. For example, the program inhibit voltage Vinhibit may be VDD, and the value range for the voltage value of the program inhibit voltage Vinhibit may be 2 V-3 V. After a certain voltage settling period, at the fourth point of time Q4 when the voltage on the selected bit line stabilizes to the ground voltage Vss and the voltage on the unselected bit lines stabilizes to the program inhibit voltage Vinhibit, the programming voltage Vpgm is applied to the selected word line connected to the at least a portion of the first memory cells and second memory cells, a third pass voltage Vpass3 is applied to the unselected word line, a third select voltage Vbsg3 is applied to the selected BSG, a fourth select voltage Vstg2 is applied to the selected TSG, and the ground voltage Vss is applied to the unselected TSG and unselected BSG.

Here, applying corresponding voltages (the programming voltage Vpgm or third pass voltage Vpass3) to the word lines after the bit line voltages have stabilized can prevent accidental programming or interference caused by unstable bit line voltages. Moreover, phased operations can avoid simultaneous switching of multiple high-voltage sources, thereby reducing transient current and power consumption.

In other examples, during the program operation, the third point of time Q3 and the fourth point of time Q4 may also be the same point of time. In other words, voltages are respectively applied to bit lines and word lines at the same point of time during the program operation, thereby eliminating the need to wait for bit line voltage stabilization and shortening the programming cycle to improve throughput.

In some examples, the third select voltage Vbsg3 applied to the selected BSG may be the ground voltage Vss to switch off the corresponding bottom select transistor. The voltage of the fourth select voltage Vstg2 applied to the selected TSG is still greater than the threshold voltage of the top select transistor.

In the process of above program operation, the target memory cells for the program operation are at least a portion of the first memory cells and the second memory cells. The selection of target memory cells depends on the target memory states of the first memory cells or the second memory cells. In some examples, the memory cells requiring the program operation are the target memory cells (also referred to as selected memory cells).

In some examples, the number of bits stored in each of the memory cells is N, the target memory state is one memory state among 2^{N} memory states comprising a second erased state and 2^{N}-1 non-erased states, N is a positive integer, and wherein a maximum threshold voltage of a threshold voltage distribution for the second erased state is less than the first verification voltage, and a minimum threshold voltage of the threshold voltage distribution for the second erased state is greater than a maximum threshold voltage of a threshold voltage distribution for a highest programmed state among the 2^{N}-1 non-erased states.

In some examples, as shown in FIG. 12, the number of bits stored in the memory cell is 2, the target memory state is one memory state among 4 memory states comprising the second erased state ER2 and 3 non-erased states (P1-P3). The maximum threshold voltage V2 of a threshold voltage distribution for the second erased state ER2 is less than the first verification voltage Vref0, and the minimum threshold voltage V3 of the threshold voltage distribution for the second erased state ER2 is greater than a maximum threshold voltage V4 of a threshold voltage distribution for a highest programmed state (P1) among the 3 non-erased states.

In some examples, among the first group of memory cells, the first memory cells whose target storage state is the second erased state ER2 serve as non-target memory cells in the program operation. In other words, after the first verification operation, the threshold voltages of these non-target memory cells are already in the second erased state ER2 and no longer need to undergo further program operations. Among the first group of memory cells, the first memory cells whose target storage state is one of the 2^{N}-1 non-erased states serve as target memory cells in the programming operation. During the program operation, these target memory cells in the first group of memory cells need to be further programmed from the second erased state ER2 to one of the 2^{N}-1 non-erased states.

In some examples, all the second memory cells in the second group of memory cells serve as target memory cells in the program operation. In other words, the threshold voltages for all the second memory cells in the second group of memory cells are all greater than or equal to the first verification voltage. For those second memory cells, among the second group of memory cells, whose target storage state is the second erased state ER2, they need to be programmed to the second erased state ER2 during the program operation. For those second memory cells, among the second group of memory cells, whose target storage state is one of the 2^{N}-1 non-erased states, they need to be programmed to one of the 2^{N}-1 non-erased states during the program operation.

It should be noted that the number of program operations illustrated in FIG. 13 is merely an example and does not limit the number of program operations disclosed herein. In practical applications, the number of program operations can be configured according to the target memory states of the first memory cells and second memory cells.

In some examples, the peripheral circuit is configured to apply a read voltage to the selected word line and apply a second pass voltage to the unselected word line during a read operation after the program operation, wherein the second pass voltage is greater than or equal to the first verification voltage and less than the first pass voltage.

In some examples, the second pass voltage is less than a maximum threshold voltage of the threshold voltage distribution for the first erased state.

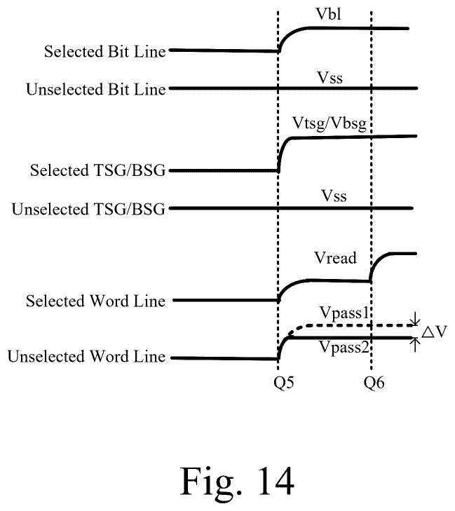

The process of the read operation is described in detail below with reference to FIG. 12 and FIG. 14.

When a read operation is performed on the MLC-type memory cell, as shown in FIG. 12 and FIG. 14, at a first point of time Q5 of the read operation, a read voltage Vread is applied to the selected word line and a second pass voltage Vpass2 is applied to the unselected word line, a voltage Vbl is applied to the selected bit line, a ground voltage Vss is applied to the unselected bit line, a select voltage Vtsg/Vbsg is applied to the selected TSG and the selected BSG, and a ground voltage Vss is applied to the unselected TSG and the unselected BSG.

In some examples, the voltage settling period for the selected word line is greater than the time interval between the first point of time Q5 and the second point of time Q6 of the read operation shown in FIG. 14.

In other examples, the time interval between the first point of time Q5 and the second point of time Q6 of the read operation is the voltage settling period.

In some examples, the second pass voltage Vpass2 is greater than or equal to the first verification voltage Vref0 and less than the first pass voltage Vpass1. The first pass voltage Vpass1 is greater than the maximum threshold voltage V1 of the threshold voltage distribution for the first erased state ER1. As shown in FIG. 14, there is a voltage difference ΔV between the first pass voltage Vpass1 and the second pass voltage Vpass2.

Here, the voltage value of the read pass voltage Vpass shown in FIG. 8 and FIG. 11 is equal to the voltage value of the first pass voltage Vpass1.

It can be understood that by adding the first verification operation prior to the program operation, a narrower final threshold voltage distribution is obtained after the program operation, which reduces the read pass voltage applied to the unselected word lines during read operations. In some examples, reducing the read pass voltage from a first pass voltage to a second pass voltage further alleviates issues caused by read disturbances and improves the performance and reliability of the memory device and the system thereof.

In some examples, the number of bits stored in each of the memory cells is N, the target memory state is one memory state among 2^{N} memory states comprising a second erased state and 2^{N}-1 non-erased states, N is a positive integer, and wherein a maximum threshold voltage of a threshold voltage distribution for the second erased state is less than the first verification voltage, and a minimum threshold voltage of the threshold voltage distribution for the second erased state is greater than a maximum threshold voltage of a threshold voltage distribution for a highest programmed state among the 2^{N}-1 non-erased states.

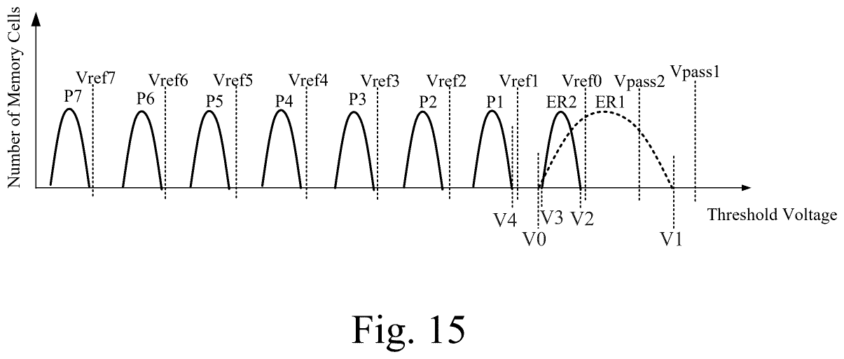

In some examples, as shown in FIG. 15, the number of bits stored in the memory cell is 3, the target memory state is one memory state among the 8 memory states comprising the second erased state ER2 and 7 non-erased states (the first memory state P1, the second memory state P2, the third memory state P3, the fourth memory state P4, the fifth memory state P5, the sixth memory state P6, and the seventh memory state P7), wherein the maximum threshold voltage V2 of the threshold voltage distribution for the second erased state ER2 is less than the first verification voltage Vref0, and the minimum threshold voltage V3 of the threshold voltage distribution for the second erased state ER2 is greater than the maximum threshold voltage V4 of the threshold voltage distribution for the highest programmed state (P1) among the 7 non-erased states.

In some examples, after the program operation, eight memory states (ER2 and P1-P7) may be verified during a program verify operation using one or more program verify voltages Vref1, Vref2, Vref3, Vref4, Vref5, Vref6 and Vref7.

It should be noted that the first verification operation, the program operation and the read operation illustrated in FIG. 12-FIG. 14 are also applicable to the QLC-type memory cell shown in FIG. 15, and for brevity, FIG. 15 may be understood with reference to the related description of FIG. 12-FIG. 14, and details are not described herein again.

In some examples, the memory device includes a ferroelectric memory. For example, the memory device includes a three-dimensional NAND-type ferroelectric memory.

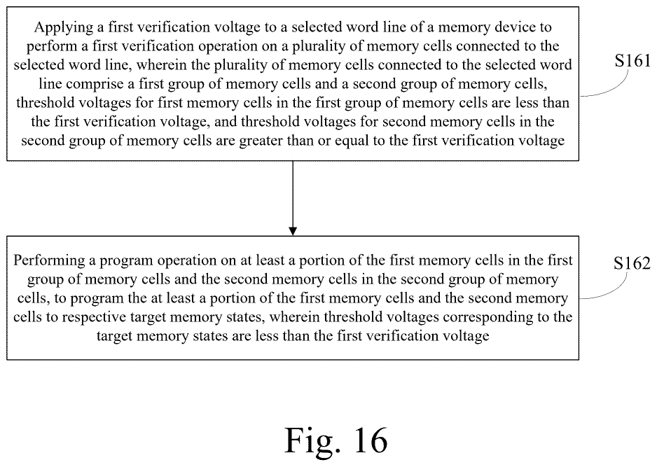

Based on a similar concept as the above memory device, the present disclosure further provides an operating method for a memory device, and FIG. 16 is a schematic flowchart of the operating method for the memory device provided by an example of the present disclosure. As shown in FIG. 16, the operating method for the memory device includes the following operations:

At S161: applying a first verification voltage to a selected word line of the memory device to perform a first verification operation on a plurality of memory cells connected to the selected word line, wherein the plurality of memory cells connected to the selected word line comprise a first group of memory cells and a second group of memory cells, threshold voltages for first memory cells in the first group of memory cells are less than the first verification voltage, and threshold voltages for second memory cells in the second group of memory cells are greater than or equal to the first verification voltage.

At S162: performing a program operation on at least a portion of the first memory cells in the first group of memory cells and the second memory cells in the second group of memory cells, to program the at least a portion of the first memory cells and the second memory cells to respective target memory states, wherein threshold voltages corresponding to the target memory states are less than the first verification voltage.

In some examples, referring to FIG. 12, the operating method for the memory device further comprises: performing an erase operation on a memory block comprising the plurality of memory cells connected to the selected word line prior to the first verification operation, to cause all the plurality of memory cells in the memory block to be in a first erased state, wherein the first verification voltage is greater than a minimum threshold voltage of a threshold voltage distribution for the first erased state and less than a maximum threshold voltage of the threshold voltage distribution for the first erased state.

In some examples, referring to FIG. 12 and FIG. 13, the operating method for the memory device further comprises: applying a first pass voltage to an unselected word line of the memory device during the first verification operation, wherein the first pass voltage is greater than the maximum threshold voltage of the threshold voltage distribution for the first erased state.

In some examples, referring to FIG. 12 and FIG. 13, the operating method for the memory device further comprises: applying a first voltage to a selected bit line of the memory device and applying a second voltage to an unselected bit line of the memory device during the first verification operation, wherein the first voltage is greater than the second voltage.

In some examples, referring to FIG. 12 and FIG. 14, the operating method for the memory device further comprises: applying a read voltage to the selected word line and applying a second pass voltage to the unselected word line during a read operation after the program operation, wherein the second pass voltage is greater than or equal to the first verification voltage and less than the first pass voltage.

In some examples, referring to FIG. 12 and FIG. 13, the second pass voltage is less than the maximum threshold voltage of the threshold voltage distribution for the first erased state.

In some examples, referring to FIG. 12 and FIG. 13, the operating method for the memory device further comprises: during the program operation, applying a programming voltage to the selected word line connected to the at least a portion of the first memory cells and the second memory cells, and applying a third pass voltage to an unselected word line.

In some examples, the number of bits stored in each of the memory cells is N, the target memory state is one memory state among 2^{N} memory states comprising a second erased state and 2^{N}-1 non-erased states, N is a positive integer, and wherein a maximum threshold voltage of a threshold voltage distribution for the second erased state is less than the first verification voltage, and a minimum threshold voltage of the threshold voltage distribution for the second erased state is greater than a maximum threshold voltage of a threshold voltage distribution for a highest programmed state among the 2^{N}-1 non-erased states.

In some examples, a value range for a voltage value of the first verification voltage is 3 V-4 V. For example, the value of the voltage value of the first verification voltage may comprise 3 V, 3.25 V, 3.5 V, or 4 V.

In some examples, the memory device includes a ferroelectric memory. For example, the memory device includes a three-dimensional NAND-type ferroelectric memory.

The operating method mentioned in the foregoing examples has been described in detail in the foregoing examples of the memory device, and details are not described herein again for brevity.

An example of the present disclosure further provides a memory system, includes: at least one memory device according to any one of the preceding examples; and a controller coupled to the memory device and configured to control the memory device.

The memory controller herein may comprise the memory controller 104 shown in FIG. 1, FIG. 2, FIG. 3 and FIG. 10, and the memory device herein may comprise the memory device 103 shown in FIG. 1 to FIG. 4 and FIG. 10. Further details about the memory controller and the memory device are described in detail above, and the structure and composition of the memory system may refer to the detailed description of FIG. 1, FIG. 2, FIG. 3 and FIG. 10, which are not described herein again for brevity.

Based on the above operating method for the memory device, the example of the present disclosure further provides a computer-readable storage medium, having stored thereon a computer program that, when executed by a processor, performs the operating method for the memory device described in any of the above examples.

Here, all or part of the processes in the operating method for the memory device in the above examples can be implemented by instructing related hardware through a computer program, and the program can be stored in a computer-readable storage medium. When the program is executed, the processes of the examples of the above methods can be implemented. The computer-readable storage medium 601 may comprise a ferromagnetic random access memory (FRAM), a read-only memory (ROM), a programmable read-only memory (PROM), an erasable programmable read-only memory (EPROM), an electrically erasable programmable read-only memory (EEPROM), a flash memory, a magnetic surface memory, an optical disk, or a compact disc read-only memory (CD-ROM) or other memory; or the storage medium may comprise a combination of the above type of memories.

The features disclosed in the several device examples provided in the present disclosure may be arbitrarily combined to obtain a new device example without conflict.

The methods disclosed in the several method examples provided in the present disclosure may be arbitrarily combined to obtain a new method example without conflict.

The above description is only a specific example of the present disclosure, but the protection scope of the present disclosure is not limited thereto. Any person skilled in the art can easily think of changes or substitutions within the technical scope disclosed in the present disclosure, which should be comprised in the protection scope of the present disclosure.

What is claimed is:

1. A memory device, comprising:
a memory cell array comprising memory cells;
a plurality of word lines coupled to the memory cell array; and
a peripheral circuit coupled to the memory cell array and configured to:
apply a first verification voltage to a selected word line to perform a first verification operation on a plurality of memory cells connected to the selected word line, wherein the plurality of memory cells connected to the selected word line comprise a first group of memory cells and a second group of memory cells, threshold voltages for first memory cells in the first group of memory cells are smaller than the first verification voltage, and threshold voltages for second memory cells in the second group of memory cells are greater than or equal to the first verification voltage; and
perform a program operation on at least a portion of the first memory cells in the first group of memory cells and the second memory cells in the second group of memory cells, to program the at least a portion of the first memory cells and the second memory cells to respective target memory states, wherein threshold voltages corresponding to the target memory states are smaller than the first verification voltage.

2. The memory device according to claim 1, wherein the peripheral circuit is further configured to:
perform an erase operation on a memory block comprising the plurality of memory cells connected to the selected word line prior to the first verification operation, to cause the plurality of memory cells in the memory block to be in a first erased state, wherein the first verification voltage is greater than a minimum threshold voltage of a threshold voltage distribution for the first erased state and smaller than a maximum threshold voltage of the threshold voltage distribution for the first erased state.

3. The memory device according to claim 2, wherein the peripheral circuit is configured to:
apply a first pass voltage to an unselected word line during the first verification operation, wherein the first pass voltage is greater than the maximum threshold voltage of the threshold voltage distribution for the first erased state.

4. The memory device according to claim 3, further comprising:
a plurality of bit lines coupled to the memory cell array,
wherein the peripheral circuit is configured to:
apply a first voltage to a selected bit line and apply a second voltage to an unselected bit line during the first verification operation, wherein the first voltage is greater than the second voltage.

5. The memory device according to claim 3, wherein the peripheral circuit is configured to:
during a read operation after the program operation, apply a read voltage to the selected word line and apply a second pass voltage to the unselected word line, wherein the second pass voltage is greater than or equal to the first verification voltage and smaller than the first pass voltage.

6. The memory device according to claim 5, wherein the second pass voltage is smaller than the maximum threshold voltage of the threshold voltage distribution for the first erased state.

7. The memory device according to claim 1, wherein the peripheral circuit is configured to:
during the program operation, apply a programming voltage to the selected word line connected to the at least a portion of the first memory cells and the second memory cells, and apply a third pass voltage to an unselected word line.

8. The memory device according to claim 1, wherein a number of bits stored in each of the memory cells is N, the target memory state is one memory state among 2^{N} memory states comprising a second erased state and 2^{N}-1 non-erased states, N is a positive integer, and
wherein a maximum threshold voltage of a threshold voltage distribution for the second erased state is smaller than the first verification voltage, and a minimum threshold voltage of the threshold voltage distribution for the second erased state is greater than a maximum threshold voltage of a threshold voltage distribution for a highest programmed state among the 2^{N}-1 non-erased states.

9. The memory device according to claim 1, wherein a value range for a voltage value of the first verification voltage is 3 V-4 V.

10. The memory device according to claim 1, comprising a ferroelectric memory.

11. An operating method for a memory device, comprising:
applying a first verification voltage to a selected word line of the memory device to perform a first verification operation on a plurality of memory cells connected to the selected word line, wherein the plurality of memory cells connected to the selected word line comprise a first group of memory cells and a second group of memory cells, threshold voltages for first memory cells in the first group of memory cells are smaller than the first verification voltage, and threshold voltages for second memory cells in the second group of memory cells are greater than or equal to the first verification voltage; and
performing a program operation on at least a portion of the first memory cells in the first group of memory cells and the second memory cells in the second group of memory cells, to program the at least a portion of the first memory cells and the second memory cells to respective target memory states, wherein threshold voltages corresponding to the target memory states are smaller than the first verification voltage.

12. The operating method according to claim 11, further comprising:
performing an erase operation on a memory block comprising the plurality of memory cells connected to the selected word line prior to the first verification operation, to cause the plurality of memory cells in the memory block to be in a first erased state, wherein the first verification voltage is greater than a minimum threshold voltage of a threshold voltage distribution for the first erased state and smaller than a maximum threshold voltage of the threshold voltage distribution for the first erased state.

13. The operating method according to claim 12, further comprising:
applying a first pass voltage to an unselected word line of the memory device during the first verification operation, wherein the first pass voltage is greater than the maximum threshold voltage of the threshold voltage distribution for the first erased state.

14. The operating method according to claim 13, further comprising:
applying a first voltage to a selected bit line of the memory device and applying a second voltage to an unselected bit line of the memory device during the first verification operation, wherein the first voltage is greater than the second voltage.

15. The operating method according to claim 13, further comprising:
applying a read voltage to the selected word line and applying a second pass voltage to the unselected word line during a read operation after the program operation,
wherein the second pass voltage is greater than or equal to the first verification voltage and smaller than the first pass voltage, and wherein the second pass voltage is smaller than the maximum threshold voltage of the threshold voltage distribution for the first erased state.

16. The operating method according to claim 11, further comprising:
during the program operation, applying a programming voltage to the selected word line connected to the at least a portion of the first memory cells and the second memory cells, and applying a third pass voltage to an unselected word line.

17. The operating method according to claim 11, wherein a number of bits stored in each of the memory cells is N, the target memory state is one memory state among 2^{N} memory states comprising a second erased state and 2^{N}-1 non-erased states, N is a positive integer, and
wherein a maximum threshold voltage of a threshold voltage distribution for the second erased state is smaller than the first verification voltage, and a minimum threshold voltage of the threshold voltage distribution for the second erased state is greater than a maximum threshold voltage of a threshold voltage distribution for a highest programmed state among the 2^{N}-1 non-erased states.

18. The operating method according to claim 11, wherein a value range for a voltage value of the first verification voltage is 3 V-4 V.

19. The operating method according to claim 11, wherein the memory device comprises a ferroelectric memory.

20. A memory system, comprising:
at least one memory device, wherein each of the at least one memory device comprises:
a memory cell array comprising memory cells;
a plurality of word lines coupled to the memory cell array; and
a peripheral circuit coupled to the memory cell array and configured to:
apply a first verification voltage to a selected word line to perform a first verification operation on a plurality of memory cells connected to the selected word line, wherein the plurality of memory cells connected to the selected word line comprise a first group of memory cells and a second group of memory cells, threshold voltages for first memory cells in the first group of memory cells are smaller than the first verification voltage, and threshold voltage for second memory cells in the second group of memory cells are greater than or equal to the first verification voltage; and
perform a program operation on at least a portion of the first memory cells in the first group of memory cells and the second memory cells in the second group of memory cells, to program the at least a portion of the first memory cells and the second memory cells to respective target memory states, wherein threshold voltages corresponding to the target memory states are smaller than the first verification voltage; and
a controller coupled to the memory device and configured to control the memory device.
